(19) United States
(12) Patent Application Publication
(10) Pub. No.: US 2025/0287614 A1
(43) Pub. Date: Sep. 11, 2025

(54) COWOS IC STRUCTURE WITH EDGE-PAD SEMICONDUCTOR DIE

(71) Applicants: ND-HI TECHNOLOGIES LAB, INC., TAIPEI CITY (TW); ETRON TECHNOLOGY, INC., HSINCHU (TW)

(72) Inventors: HO-MING TONG, TAIPEI CITY (TW); CHAO-CHUN LU, HSINCHU (TW)

(21) Appl. No.: 19/214,066

(22) Filed: May 21, 2025

Related U.S. Application Data
(63) Continuation-in-part of application No. 18/471,670, filed on Sep. 21, 2023.
(60) Provisional application No. 63/409,852, filed on Sep. 26, 2022.
(60) Provisional application No. 63/730,072, filed on Dec. 10, 2024.

(51) Int. Cl. H10B 80/00; H01L 25/065; H01L 25/18

(52) U.S. Cl. CPC H10B 80/00; H01L 25/0657; H01L 25/18; H01L 2225/06541; H01L 2225/06551; H01L 2225/06589

(57) ABSTRACT

An IC structure includes a memory stack, which includes a plurality of semiconductor dies horizontally separate with each other, a memory controller chip, an interposer, a logic processor chip and a packaging substrate. Each semiconductor die includes a top surface, a bottom surface, and four sidewalls, and a plurality of edge pads are arranged along the first sidewall. The memory controller chip is disposed under and electrically connected to the plurality of edge pads of each semiconductor die, wherein the first sidewall of each semiconductor die faces the memory controller chip. The interposer is disposed under and electrically connected to the memory controller chip. The logic processor chip is electrically connected to the memory controller chip. The packaging substrate is disposed under and electrically connected to the interposer.

### PRIORITY CLAIM AND CROSS-REFERENCE

This application claims the benefit of U.S. provisional application No. 63/730,072 filed Dec. 10, 2024, and is a continuation-in-part application of U.S. non-provisional application Ser. No. 18/471,670 filed Sep. 21, 2023, which claims the benefit of U.S. provisional applications No. 63/409,852 filed Sep. 26, 2022, the disclosures of all of which are incorporated by reference herein in their entirety.

### FIELD

This disclosure relates in general to a COWOS IC structure, and more particularly to a COWOS IC structure with edge-pad semiconductor die.

### BACKGROUND

2.5D/3D ICs have been recognized as a next generation semiconductor technology, which has the advantage of high performance, low power consumption, small physical size and high integration density. 2.5D/3D ICs provide a path to continue to meet the performance/cost demands of next generation devices while remaining at more relaxed gate lengths with less process complexity. Thus, 2.5D/3D ICs are expected to find broad based utilities in applications such as HPC (high-performance computing) and data centers, AI (artificial intelligence)/ML (machine learning), 5G/6G networks, graphics, smart phones/wearables, automotive and others that demand “extreme,” ultra-high-performance, higher-power-efficiency devices.

Commercial 2.5D/3D ICs such as a 3D high-bandwidth memory (HBM) DRAM memory die stack on logic are increasingly being used, and those HBM devices contain through silicon vias (TSVs) in both active dies and in the silicon interposer. Furthermore, 2.5D/3D ICs also allow for vertical stacking of heterogeneous dies from different manufacturing processes and nodes, chip reuse and chiplets-in-SiP (system-in-a-package) for high-performance applications, which have been already pushing the limits of a single die at the most advanced node. As shown in FIG. 1, a COWOS (chips-on-wafer-on-substrate) structure 20 includes an HBM structure 21 (with a plurality of DRAM memory dies 211 and a controller 212) with TSVs 201, a logic die 22 (such as a GPU or an SOC chip), a silicon interposer 23 with TSVs and a packaging substrate 24, wherein the HBM structure 21 and the logic die 22 are stacked on the silicon interposer 23, and the silicon interposer 23 is then stacked on the packaging substrate 24.

However, 2.5D/3D ICs adopt packaging topologies with bottom/top electrical interconnects created by the aforementioned interconnect technologies such as micro-bumps, TSVs and redistribution layers (RDL). The bottom/top electrical interconnects impose a severe constraint on PPAC (power, performance, area and cost) optimization by designers of 3D ICs to come up with optimal design solutions, especially the difficulty of forming TSVs in semiconductor dies and the alignment of TSVs for each semiconductor die.

Furthermore, as the monolithic integration capability of a silicon chip has grown from GSI (Giga Scale Integration: Over billions of transistors on a die) toward TSI (Tera Scale Integration: Trillions of transistors on a die) soon, the power consumption of running such a huge number of transistors is increasing sharply, which elevates adversely the junction temperature of transistors and thus the entire chip temperature due to current limited heat-dissipation capability (e.g. Thermal conductivity index of silicon dioxide/silicon is very low. To be worse, due to the stack of multiple DRAM memory semiconductor dies (or HBM) in 2.5D/3D ICs, the insufficient heat dissipation problem causing higher temperature to chip operation is regarded as the worst problem for the HBM structure.

### SUMMARY

According to a first aspect of the present disclosure, an IC structure includes a memory stack, a memory controller chip, an interposer, a logic processor chip and a packaging substrate. The memory stack includes a plurality of semiconductor dies. The plurality of semiconductor dies are horizontally separate with each other, wherein each semiconductor die includes a top surface, a bottom surface opposite to the top surface, and four sidewalls with a first sidewall, a second sidewall, a third sidewall and a fourth sidewall, and a plurality of edge pads arranged along the first sidewall, wherein the area of the bottom surface or the top surface of each semiconductor die is larger than that of any sidewall. The memory controller chip is disposed under and electrically connected to the plurality of edge pads of each semiconductor die, wherein the first sidewall of each semiconductor die faces the memory controller chip. The interposer is disposed under and electrically connected to the memory controller chip. The logic processor chip is electrically connected to the memory controller chip. The packaging substrate is disposed under and electrically connected to the interposer.

According to some embodiments of the present disclosure, the memory stack further includes an upward extending thermal conductivity layer and/or a laterally extending thermal conductivity layer. The laterally extending thermal conductivity layer covers each second sidewall of the plurality of semiconductor dies. The upward extending thermal conductivity layer is attached to the top surface or the bottom surface of a first semiconductor die, wherein the thermal conductivity of the laterally extending thermal conductivity layer or the upward extending thermal conductivity layer is higher than that of Si or SiO₂.

According to some embodiments of the present disclosure, the upward extending thermal conductivity layer is thermally coupling to the laterally extending thermal conductivity layer, and the upward extending thermal conductivity layer or the laterally extending thermal conductivity layer includes SiC, BN, AlN, W, or copper.

According to some of the present disclosure, the upward extending thermal conductivity layer is disposed between the first semiconductor die and a second semiconductor die, or the upward extending thermal conductivity layer is located at a most lateral sidewall of the memory stack.

According to some embodiments of the present disclosure, each semiconductor die is a DRAM die and includes data output between 128˜2048 bits.

According to some embodiments of the present disclosure, each edge pad of each semiconductor die includes an edge contact in a back-end-of-line (BEOL) region and a conductive via over the edge contact and in a dielectric layer or a redistribution layer (RDL), wherein the area of the conductive via is larger than that of the edge contact.

According to some embodiments of the present disclosure, the edge contact electrically connects to a signal pad in the BEOL region of the semiconductor die surrounded by a seal ring structure.

According to some embodiments of the present disclosure, each edge pad of each semiconductor die includes a conductive line in a redistribution layer (RDL), the conductive line electrically connected to a signal pad in a back-end-of-line (BEOL) region of the semiconductor die surrounded by a seal ring structure.

According to some embodiments of the present disclosure, the RDL includes a plurality of stacked dielectric layers within which the conductive line is located.

According to some embodiments of the present disclosure, a portion of the conductive line is configured to be disposed in a scribe line region of a semiconductor wafer prior to dicing of the semiconductor wafer.

According to some embodiments of the present disclosure, the logic processor chip is disposed over the interposer, and a heat sink is over the logic processor chip; wherein a top surface of the heat sink is substantially leveled up with that of the memory stack.

According to some embodiments of the present disclosure, the memory stack further includes an upward extending thermal conductivity layer covering each third sidewall of the plurality of semiconductor dies; wherein the upward extending thermal conductivity layer is thermally coupling to a laterally extending thermal conductivity layer over each second sidewall of the plurality of semiconductor dies, and the thermal conductivity of the upward extending thermal conductivity layer is higher than that of Si or SiO₂.

### BRIEF DESCRIPTION OF THE DRAWINGS

Aspects of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 shows a conventional semiconductor COWOS structure with high-bandwidth memory (HBM).

FIGS. 2(a) and 2 (b) show a perspective view and a cross-sectional view, respectively, of a memory die with multiple edge pads, according to some embodiments of the present disclosure.

FIGS. 2(c) shows a cross-sectional view of a semiconductor wafer containing memory dice with multiple edge pads, according to some embodiments of the present disclosure.

FIGS. 2(d) and 2 (e) show cross-sectional views of another memory die with multiple edge pads, according to some embodiments of the present disclosure.

FIG. 3(a) shows a perspective view of a conventional high-bandwidth memory (HBM) structure.

FIG. 3(b) shows a perspective view of a new high-bandwidth memory (NuHBM) stack or shelf, according to some embodiments of the present disclosure.

FIG. 4 shows cross-sectional views of intermediate stages of forming a NuHBM stack or shelf, according to some embodiments of the present disclosure.

FIGS. 5(a) to 5 (d) show a NuHBM stack or shelf interconnection process, according to some embodiments of the present disclosure.

FIG. 6 shows an IC structure with a NuHBM stack or shelf, according to some embodiments of the present disclosure.

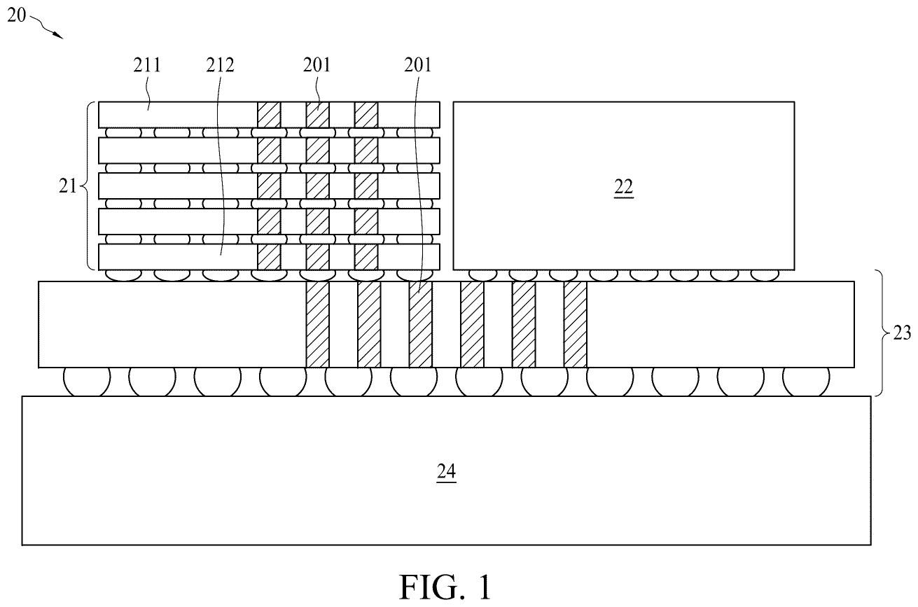

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

In this invention, the side face(s) of memory dies are used for interconnecting dies in the 2.5D/3D IC stack to allow for skip-die signals and power distribution. Moreover, the high thermal conductivity material is disposed between two adjacent memory dies and thermally coupled to another high thermal conductivity material covering other side face of memory dies stack.

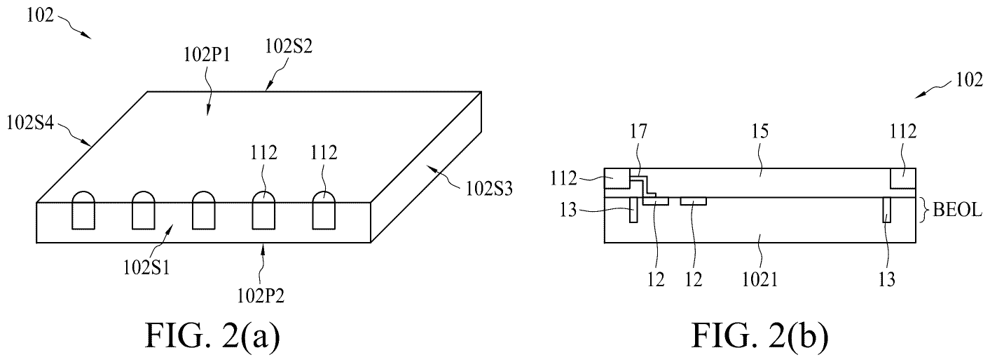

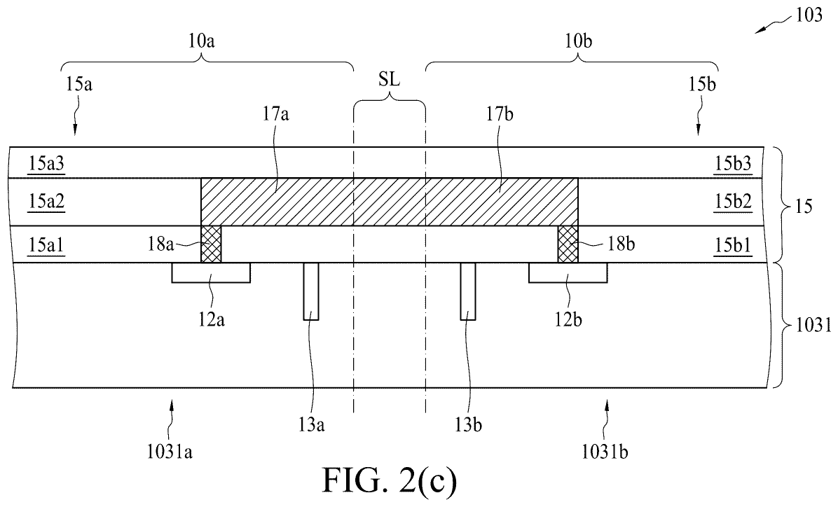

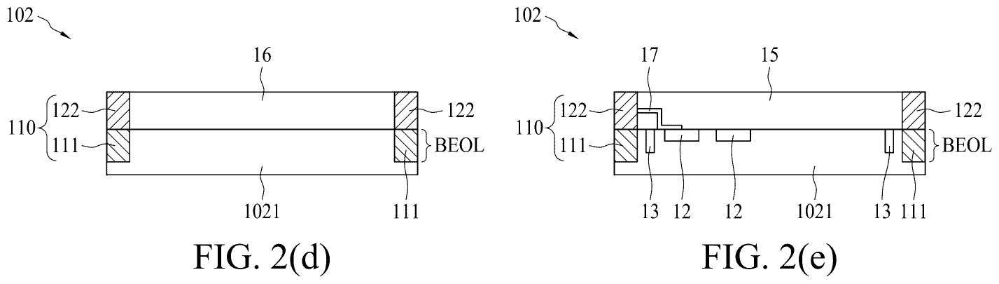

FIG. 2(a) show a perspective view and a cross-sectional view of an edge-pad semiconductor die (or semiconductor die hereinafter) 102 according to some embodiments of the present disclosure. The edge-pad semiconductor die 102 has a top surface 102P1, a bottom surface 102P2, and four sidewalls 102S1, 102S2, 102S3, and 102S4, wherein the area of the top surface/bottom surface 102P1/102P2 is far larger than those of the sidewalls 102S1, 102S2, 102S3, and 102S4 (as shown in FIG. 2(a)). The semiconductor die 102 further includes “edge pads” 112 in the form of peripheral pads residing at the periphery or side faces or sidewalls (such as sidewalls 102S1, 102S2, 102S3, and/or 102S4) of the edge-pad semiconductor die 102 in FIG. 2(a).

Further, throughout the present disclosure, multiple edge-pad semiconductor dies 102 arranged in a stack or shelf can be named as new high bandwidth memory (NuHBM) or NuHBM system. Hereinafter, the NuHBM system may be also referred to the memory stack or memory shelf (or NuHBM stack or NuHBM shelf), which includes a plurality of edge-pad semiconductor dies or exemplary semiconductor die 102 shown in FIG. 2(a).

Referring to FIG. 2(b), in one embodiment, the edge-pad semiconductor die 102 includes a memory die 1021 and a redistribution layer (RDL) 15 over a top surface of the memory die 1021. The memory die 1021 can also be a DRAM die. In one embodiment, there is no through-silicon-vias (TSVs) in the memory die 1021 of the edge-pad semiconductor die 102 which includes edge pads along one the side surface. There are one or more signal pads 12 within the memory die 1021, and a seal ring 13 surrounding the signal pad 12. The memory die 1021 may include a BEOL (back end of line) region arranged on a front side of the memory die 1021. In one embodiment, each edge pad 112 of each semiconductor die 102 includes the conductive line 17 in the redistribution layer 15 (RDL), and the conductive line 17 is electrically connected to the signal pad 12 in the back-end-of-line (BEOL) region of the semiconductor die 102 surrounded by the seal ring 103. Referring to FIG. 2(b), in the substrate of the memory die 1021, all signal pads 12 are located within a region defined by the seal ring 13 of the substrate, and the edge pads 112 are located in the RDL 15 and electrically connected to the signal pads 12 (see of FIG. 2(b)) in the BEOL region. If necessary, additional edge redistribution layer (RDL) could be formed to cover those edge-pads 112 of the NuHBM stack to create larger edge bumps or larger edge pads within the edge RDL.

In some embodiments, the interconnect structure of the RDL 15 may include a plurality of conductive line layers, a plurality of conductive vias, and one or more edge pads 112. The conductive lines, conductive vias and edge pads together construct the various conduction paths of the interconnect structure. FIG. 2(b) shows a conductive line 17 and vertical conductive vias arranged in the RDL 15 and electrically connecting the signal pad 12 to the edge pads 112.

FIG. 2(c) shows a cross-sectional view of a portion semiconductor wafer 103 containing multiple edge-pad semiconductor dies according to some embodiments of the present disclosure. In some embodiments, as shown in FIG. 2(c), a plurality of edge-pad semiconductor dies, e.g., exemplary edge-pad semiconductor dies 10a and 10b, are formed on a semiconductor wafer 103. The boundaries of the adjacent edge-pad semiconductor dies 10a and 10b are defined by scribe line regions SL. In some embodiments, each edge-pad semiconductor die 10a or 10b includes a memory die 1031a or 1031b and an RDL 15a or 15b disposed over the respective memory die 1031a or 1031b. The memory die 1031a or 1031b further includes signal pads 12a or 12b, and seal rings 13a or 13b, in the memory dies 1031a and 1031b, respectively. Furthermore, the RDL 15a or 15b includes one or more conductive lines 17a or 17b or vias 18a or 18b, whichever appropriate for RDL design, electrically connected to the corresponding signal pads 12a or 12b, respectively. The RDL 15a (or 15b) further includes stacked dielectric or isolating layers 15a1, 15a2 and 15a3 (or 15b1, 15b2, or 15b3), within which the conductive line 17a or 17b is located. In some embodiments, the exposed portion of the conductive line or via 17a or 17b after wafer dicing performed in the scribe line region SL serves as the edge pad as previously described, such as shown in FIG. 2(b). The dielectric or isolating layers in one embodiment may be made of SiO₂.

FIGS. 2(d) and 2(e) show cross-sectional views of the edge-pad semiconductor die or chip 102, according to some embodiments of the present disclosure. In some embodiments, the memory die 1021 of the edge-pad semiconductor die 102 has edge contacts 111 formed during the manufacturing process of the BEOL region, such as formed in a M4 or M5 metal layer. To increase the contact area of the edge pad, a dielectric layer 16 with one or more conductive via 122 or conductive lines is formed over the memory die 1021. Referring to FIG. 2(d), the conductive via 122 may correspond to or be aligned with the respective edge contacts 111. In some embodiments, the area (for example, the exposed lateral area) of the conductive via 122 is greater than that of the edge contact 111. In some embodiments, the edge contact 111 is electrically or physically connected to the corresponding conductive via 122. Thus, each edge pad 110 of the edge-pad semiconductor die 102 may include an edge contact 111 and a conductive via 122. In another embodiment, the dielectric layer 16 is replaced by the RDL 15, as shown in FIG. 2(e). Same numeral labels in FIG. 2(d) and FIG. 2(e) refer to substantially identical or functionally identical components and the associated description can be referred thereto without repeating here for brevity.

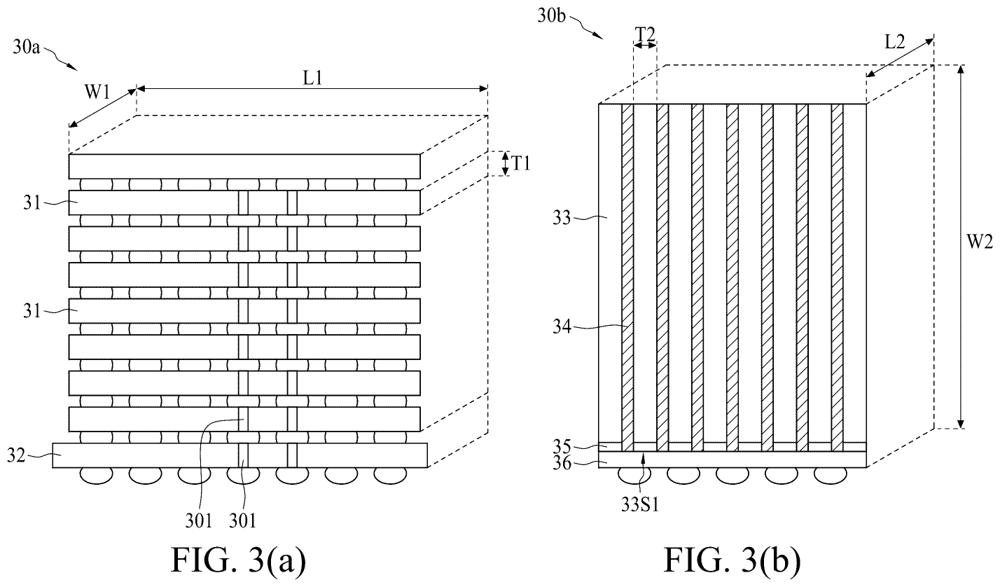

FIG. 3(a) shows a perspective view of a conventional high-bandwidth memory (HBM) structure 30a, which includes a plurality of DRAM chips 31 (such as 12 chips for HBM3 or 16 chips for HBM4) vertically stacked together above a controller 32, wherein each DRAM chip 31 has a width W1 about 9.5 mm, a length L1 about 10.5 mm, and a thinner thickness T1 about 0.05 mm due to the requirement of multiple TSVs 301 therein. Usually, four DRAM chips 31 are grouped together to output 1 K bits of data bus width, wherein each DRAM chip 31 outputs 256 bits. Thus, when 12 DRAM chips in the HBM3 configuration are divided into three group, each group with 4 DRAM chips can output 1 K bits of data, respectively.

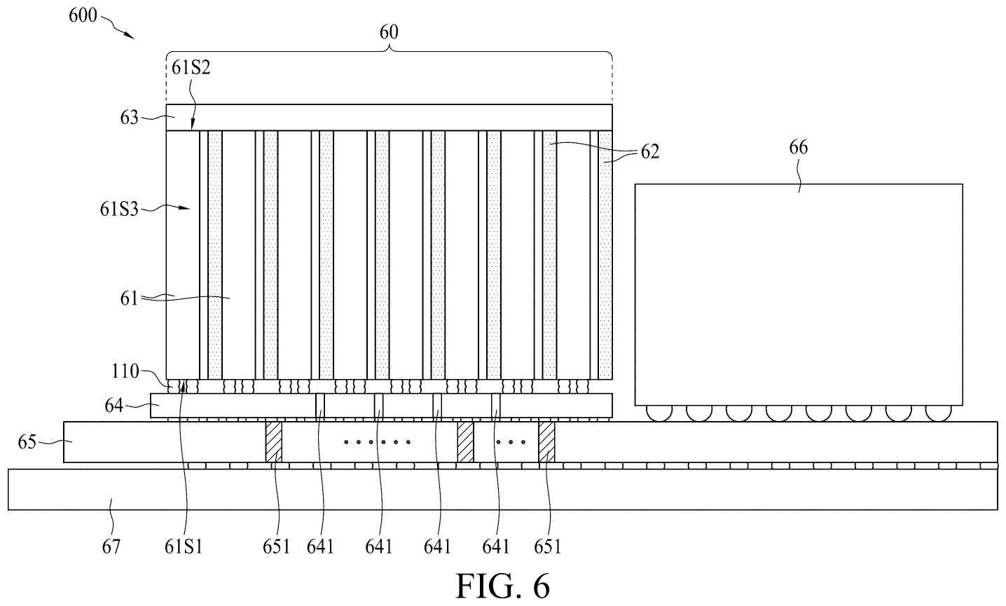

FIG. 3(b) shows a perspective view of a NuHBM stack or shelf 30b, according to some embodiments of the present disclosure. In contrast to the conventional HBM structure 30a, the NuHBM stack or shelf 30b of the present invention includes a plurality of edge-pad semiconductor dies 33, a plurality of high thermal conductivity layer 34 (optionally), and a memory controller 36. In some embodiments, the plurality of edge-pad semiconductor dies 33 are horizontally separate or horizontally stacked together, such as 16 or 24 chips or more. In some embodiments, each edge-pad semiconductor dies 33 has a width W2 of about 3 mm˜9.5 mm, a length L2 of about 10.5 mm (like the one used in the HBM stack structure 30a), and a regular thickness T2 about 50˜100 μm without TSVs therein. Moreover, for heat dissipation purposes, the high thermal conductivity “HTC” material or layer 34 (such as SiC/AlN/BN/W/Cu/undoped polysilicon/large crystalline silicon, etc.) is disposed adjacent to one edge-pad semiconductor die 33 respectively, or disposed between two disposed edge-pad semiconductor dies 33. Furthermore, although not separately shown in FIG. 3(b), one or more HTC material or layers, e.g., the top-high thermal conductivity layer 63 shown in FIG. 6, could be used to cover the top of the edge-pad semiconductor dies or chips 33 and couple to the other HTC layer 34 between the edge-pad semiconductor dies 33.

The NuHBM shelf 30b may further include a plurality of edge pads 35 arranged along a lower sidewall 33S1 in the direction of the length L2 about 10.5 mm. For example, when the hybrid bonding with a bonding pitch of about 5 μm is used, each edge-pad semiconductor die 33 has 2100 edge (I/O) pads 35 (10.5 mm/5 μm=2100) in the direction of the length L2; and when solder ball bonding with a bonding pitch of about 30 μm is used, each edge-pad semiconductor die 33 has 350 edge pads 35 (10.5 mm/30 μm=350), and when the bonding pitch is 40 μm and the length L2 is 10.5 mm, it could provide 262 edge pads 35 (with a 128-bit output data for I/O). If necessary, an edge RDL (see U.S. application Ser. No. 18/471,670 and U.S. application Ser. No. 19/059,275, all content of which is incorporated by reference herein) could be optionally used for the formation of edge pads with larger area. Therefore, suppose one half of the edge pads 35 are used for data I/O, each edge-pad semiconductor chip 33 could have 175-bit output data (assuming a bonding pitch of about 30 μm) or 1 K-bit output data (a bonding pitch of about 5 μm), or other numbers of the edge pads 35 depending on the different bonding pitches. The plurality of edge-pad semiconductor dies 33 (i.e., NuHBM stack or shelf) are electrically coupled to the memory controller 36 through the edge pads 35, such that the memory controller 36 can output the data with a desired data width based on the number of output data of one edge-pad semiconductor die 33, the combined output data of two or more edge-pad semiconductor dies 33, or the combined output data of all edge-pad semiconductor dies 33. Depending on the size of the memory chip, the edge pads thereof may include 128˜2048 bits.

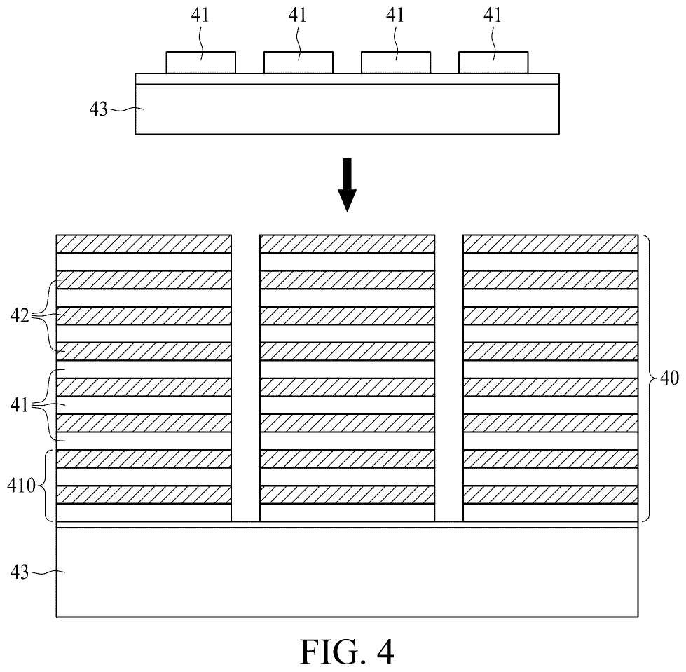

FIG. 4 shows cross-sectional views of intermediate stages of forming a NuHBM stack or shelf 40, according to some embodiments of the present disclosure. As shown in an upper plot and a lower plot of FIG. 4, multiple NuHBM stacks or shelves 40 can be formed by bonding multiple edge-pad semiconductor chips 41 and HTC layers 42 to a carrier 43, followed by:
(1) Stacking more edge-pad semiconductor chips 41 of the same size to first form a short NuHBM stack 410, wherein, a high thermal conductivity “HTC” material or layer 42 (such as AlN/BN/W/Cu/undoped polysilicon/large crystalline silicon, etc.) are inserted between two adjacent edge-pad semiconductor chips 41. In some embodiments, the thermal conductivity (or thermal conductivity coefficient) of the high thermal conductivity layer 42 is higher than that of Si or SiO₂.
(2) Combining multiple short NuHBM stacks 410 together to form the NuHBM shelf 40 which are thick enough for ease of subsequent processing.
(3) Performing carrier release of the carrier 43, and release the NuHBM shelf 40.

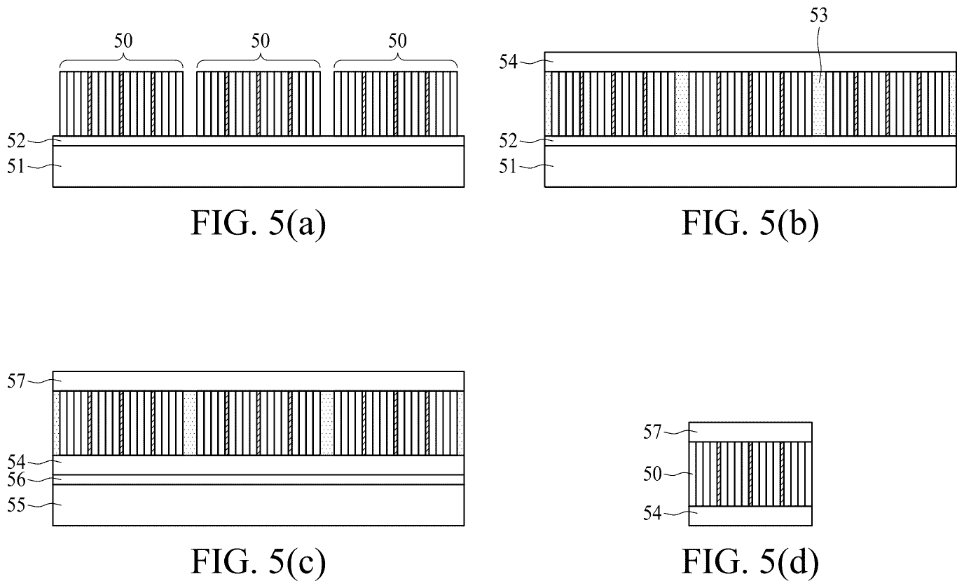

FIGS. 5(a) to 5(d) show a NuHBM stack or shelf 50 interconnection process, according to some embodiments of the present disclosure. With the NuHBM stack or shelf 50 at hand, one can then bond them sideways to another carrier 51 and pot them using a polymer material 53 such as the Epotek 377 epoxy in vacuum and curing the polymer, followed by:
(1) Bonding multiple NuHBM shelves 50 to a carrier 51 with a release layer 52, followed by potting and planarization (and a light etching or lapping to ensure all edge connections are revealed), and pot them using the polymer material 53. If necessary, additional edge RDL could be formed to cover those edge-pads of the NuHBM stack to create larger edge bumps or larger edge pads, as previously mentioned.
(2) Bonding a wafer of memory controllers 54.
(3) Bonding the multiple NuHBM shelves 50 to a carrier 55 with a release layer 56, removing the carrier 51 by releasing the release layer 52, and creating a high thermal conductivity layer 57 (or covering other one/two/three sidewalls of the tall 3D IC structure stack; or covering the rest sidewalls of the tall 3D IC structure stacks without the RDL layers).
(4) Removing the carrier 55 by releasing the release layer 56, dicing, and release the NuHBM Shelf 50 with memory controller die (memory controller) 54 and the high thermal conductivity layer 57.

Therefore, the released NuHBM shelf with the memory controller could replace HBMs in the conventional COWOS structure, as shown in FIG. 6. FIG. 6 shows a COWOS IC structure with a NuHBM stack or shelf, according to some embodiments of the present disclosure. As shown in FIG. 6, a memory shelf 60 includes a plurality of semiconductor dies 61, an upward extending thermal conductivity layer 62 and a top-high thermal conductivity layer 63. The plurality of semiconductor dies 61 horizontally separate with each other, wherein referring to FIG. 2(a) and FIG. 6, each semiconductor die 61 includes a top surface 102P1, a bottom surface 102P2 opposite to the top surface, and four sidewalls with a first sidewall 102S1 or 61S1, a second sidewall 102S2 or 61S2, a third sidewall 102S3 or 61S3 and a fourth sidewall 102S4, and a plurality of edge pads 110 arranged along the first sidewall 61S1, wherein the area of the bottom surface or the top surface is larger than that of any sidewall. The upward extending thermal conductivity layer 62 is disposed between two adjacent semiconductor dies 61, wherein the thermal conductivity of the upward extending thermal conductivity layer 62 is higher than that of Si or SiO₂. If necessary, adhesive layer could used between the upward extending thermal conductivity layer 62 and the semiconductor die 61.

The COWOS IC structure 600 includes the memory shelf 60 described above, a memory controller chip 64, an interposer 65, a logic processor chip 66 and a packaging substrate 67. The memory controller chip 64 is disposed right under and electrically connected to the plurality of edge pads 110 of each semiconductor die 61. The interposer 65 is disposed under and electrically connected to the memory controller chip 64. The logic processor chip 66 is electrically connected to the memory controller chip 64. The packaging substrate 67 is disposed under and electrically connected to the interposer 65. In some embodiments, the memory controller chip 64 may include a plurality of TSVs 641 for electrical connection between the edge pad of the semiconductor die 61 and the interposer 65. In some embodiments, the interposer 65 may be a silicon interposer including a plurality of TSVs 651 for electrical connection between the memory controller chip 64 and the packaging substrate 67. The interposer 65 may include some wiring on the top surface for electrical connection between the memory controller chip 64 and the logic processor chip 66. In some embodiments, the logic processor chip 66 may be disposed over the interposer 65. Additional heat sink (not shown) could be disposed over the top of the logic processor chip 66, such that the top surface of the heat sink could be leveled up with or substantially the same as the top surface of the memory shelf 60.

The NuHBM shelf 60 with memory controller chip 64 can be bonded to the interposer 65 or IC chip, as shown in FIG. 6, wherein the NuHBM shelf 60 in this embodiment includes a plurality of semiconductor dies 61 (such as DDR4 die, DDR5 die, LDDR4 die, LDDR5 die, or GDDR7 die, etc.), each semiconductor die 61 is horizontally separate from the others. The power/signals of each semiconductor die 61 could be propagated to the memory controller chip 64 without through other Semiconductor dies 61. Moreover, since there is inter-high thermal conductivity layer (or, upward extending thermal conductivity layer) 62 (such as dummy Si chip, SiC, AlN, BN, W, Copper, etc.) between two adjacent semiconductor dies 61 and connected to a top-high thermal conductivity layer 63 on other sidewall(s) of the NuHBM shelf 60, the heat generated from those two semiconductor dies 61 could be spread through the inter-high thermal conductivity layer 62 to the top-high thermal conductivity layer 63, and passed to other heat sink (not shown) connected to the top-high thermal conductivity layer 63.

In another embodiment, the upward extending thermal conductivity layer 62 between two adjacent semiconductor dies 61 could be omitted, but a top-high thermal conductivity layer 63 is still disposed on the top of the NuHBM shelf 60. In another embodiment, the upward extending thermal conductivity layer 62 is attached to the most lateral sidewall of the NuHBM, and a top-high thermal conductivity layer 63 is further disposed on the top of the NuHBM shelf 60. In another embodiment, the memory stack 60 further includes an upward extending thermal conductivity layer covering each third sidewall 61S3 of the plurality of semiconductor dies 61; wherein the upward extending thermal conductivity layer is thermally coupling to a laterally extending thermal conductivity layer (top-high thermal conductivity layer 63) over each second sidewall 61S2 of the plurality of semiconductor dies 61, and the thermal conductivity of the upward extending thermal conductivity layer is higher than that of Si or SiO₂.

In the event there is a need to have more signals transmission in the short 3D IC structure stack, as previously mentioned, more edge RDLs could be formed on two or more side faces of semiconductor dies 61. In the event there is a need to have more heat dissipation requirement, as previously mentioned, more high thermal conductivity layers could be formed on two or more side faces.

In summary, the present invention provides COWOS IC structure with a NuHBM Shelf, the NuHBM Shelf incldues a plurality of edge-pad semiconductor dies, edge pads of each semiconductor die are over the side face(s) of semiconductor die for interconnecting to allow for skip-die signal and power distribution. Moreover, the high thermal conductivity material is disposed between two adjacent edge-pad semiconductor dies and thermally coupled to another high thermal conductivity material covering other side face of the NuHBM Shelf.

1. An IC structure comprising:
a memory stack comprising:
a plurality of semiconductor dies horizontally separate with each other, wherein each semiconductor die comprises a top surface, a bottom surface opposite to the top surface, and four sidewalls with a first sidewall, a second sidewall, a third sidewall and a fourth sidewall, and a plurality of edge pads arranged along the first sidewall, wherein the area of the bottom surface or the top surface of each semiconductor die is larger than that of any sidewall;
a memory controller chip under and electrically connected to the plurality of edge pads of each semiconductor die, wherein the first sidewall of each semiconductor die faces the memory controller chip;
an interposer under and electrically connected to the memory controller chip;
a logic processor chip electrically connected to the memory controller chip; and
a packaging substrate under and electrically connected to the interposer.

2. The IC structure of claim 1, the memory stack further comprising:
a laterally extending thermal conductivity layer covering each second sidewall of the plurality of semiconductor dies; and/or
an upward extending thermal conductivity layer attached to the top surface or the bottom surface of a first semiconductor die,
wherein the thermal conductivity of the laterally extending thermal conductivity layer or the upward extending thermal conductivity layer is higher than that of Si or SiO₂.

3. The IC structure of claim 2, wherein the upward extending thermal conductivity layer is thermally coupling to the laterally extending thermal conductivity layer, and the upward extending thermal conductivity layer or the laterally extending thermal conductivity layer comprises SiC, BN, AlN, W, or copper.

4. The IC structure of claim 2, the upward extending thermal conductivity layer is disposed between the first semiconductor die and a second semiconductor die, or the upward extending thermal conductivity layer is located at a most lateral sidewall of the memory stack.

5. The IC structure of claim 1, wherein each semiconductor die is a DRAM die and includes data output between 128˜2048 bits.

6. The IC structure of claim 1, wherein each edge pad of each semiconductor die includes:
an edge contact in a back-end-of-line (BEOL) region; and
a conductive via over the edge contact and in a dielectric layer or a redistribution layer (RDL), wherein the area of the conductive via is larger than that of the edge contact.

7. The IC structure of claim 6, wherein the edge contact electrically connects to a signal pad in the BEOL region of the semiconductor die surrounded by a seal ring structure.

8. The IC structure of claim 1, wherein each edge pad of each semiconductor die includes a conductive line in a redistribution layer (RDL), the conductive line electrically connected to a signal pad in a back-end-of-line (BEOL) region of the semiconductor die surrounded by a seal ring structure.

9. The IC structure of claim 8, wherein the RDL includes a plurality of stacked dielectric layers within which the conductive line is located.

10. The IC structure of claim 9, wherein a portion of the conductive line is configured to be disposed in a scribe line region (SL) of a semiconductor wafer prior to dicing of the semiconductor wafer.

11. The IC structure of claim 1, wherein the logic processor chip is disposed over the interposer, and a heat sink is over the logic processor chip; wherein a top surface of the heat sink is substantially leveled up with that of the memory stack.

12. The IC structure of claim 1, wherein the memory stack further comprises an upward extending thermal conductivity layer covering each third sidewall of the plurality of semiconductor dies; wherein the upward extending thermal conductivity layer is thermally coupling to a laterally extending thermal conductivity layer over each second sidewall of the plurality of semiconductor dies, and the thermal conductivity of the upward extending thermal conductivity layer is higher than that of Si or SiO₂.
